(19) United States
(12) Patent Application Publication
(10) Pub. No.: US 2026/0152351 A1
(43) Pub. Date: Jun. 4, 2026

(54) APPARATUS, SYSTEM AND METHOD FOR PROVIDING AN EDGE GRIP SUBSTRATE FLIPPER

(71) Applicant: JABIL INC., St. Petersburg, FL (US)

(72) Inventors: Jeroen Bosboom, St. Petersburg, FL (US); GUNNAR HAUGEN, St. Petersburg, FL (US); BABAK NADERI, St. Petersburg, FL (US); MICHAEL PATRICK MCKENNEY, St. Petersburg, FL (US); KWOK KUEN YU, St. Petersburg, FL (US); RICHARD JAMES JAMES, St. Petersburg, FL (US)

(21) Appl. No.: 19/122,965

(22) PCT Filed: Oct. 24, 2023
(86) PCT No.: PCT/US2023/077598

§ 371 Date: Apr. 21, 2025

Related U.S. Application Data
(60) Provisional application No. 63/418,877, filed on Oct. 24, 2022.

(51) Int. Cl. H10P 72/00; H10P 72/30; H10P 72/76

(52) U.S. Cl. CPC B65G 47/248; H10P 72/7606; H10P 72/78

(57) ABSTRACT

An apparatus, system and method for a substrate flipper capable of accommodating substrates of varying sizes. The apparatus, system and method may include a base housing providing a rotating feature extending outwardly from the base housing, and including a belt driver; a flipping paddle rotatably associated with the outwardly extending portion of the rotating feature; at least two clamp rails movably resident within slots atop the flipping paddle, each of the at least two clamp rails being associated with a belt driven by the belt driver; and a pair of clamps atop each of the at least two clamp rails, wherein each pair of clamps is opposable to the other pair of clamps, each clamp comprising a lower wedge having therein a spring loaded cam, and an upper wedge against which the spring loaded cam presses an edge of the accommodated substrate upon retention-driving of the belt.

### CROSS-REFERENCE TO RELATED APPLICATIONS

This application claims priority to U.S. provisional application No. 63/418,877, filed on Oct. 24, 2022, entitled “Apparatus, System and Method for Providing an Edge Grip Substrate Flipper”, incorporated herein by reference in its entirety.

### BACKGROUND

### Field of the Disclosure

The present disclosure relates to the transfer and processing of articles, such as semiconductor wafers, and more particularly to an apparatus, system and method for providing an edge grip substrate flipper for in-process substrates.

### Description of the Background

The use of robotics is well established as a manufacturing expedient, particularly in applications where human handling is inefficient and/or undesirable. One such circumstance is in the semiconductor arts, in which robotics and automated stations are used to handle and hold wafers during various process steps. Such process steps may include, by way of example, chemical mechanical planarization (CMP), etching, deposition, passivation, and various other processes in which a sealed and/or “clean” environment must be maintained, such as to limit the likelihood of contamination and to ensure that various specific processing conditions are met.

Current practice in the semiconductor arts to robotically handle these wafers often includes the use of an end effector flipper/aligner operably attached to the robotics, such as in order to load semiconductor wafers from a loading stack into the various processing ports that may correspond to the aforementioned exemplary process steps. The robotics are employed to deploy the flipper/aligner to retrieve the wafer from a particular port or stack, such as before and/or after processing in an associated process chamber, and/or to associate the wafer with a station, such as may include a station chuck onto which the wafer is placed.

The wafer may thus be shuttled by the robotics connectively associated with the flipper/aligner between stations for additional processing. When a given wafer process is complete, the robotics may move the processed wafer from its station and return the processed semiconductor wafer to a loading port. It is typical that a stack of several semiconductor wafers is processed in this manner using the flipper/aligner-to-station movement during each process run.

The known art thus uses the end effector to flip and rotate wafers and similar substrates, such as for inspection during or after processing. However, such known flippers generally cannot handle multiple wafer/substrate sizes. As referenced throughout, not only do silicon wafer sizes vary significantly, but so too do the sizes of other substrates that the flipper may be required to handle. Therefore, the limitations on modifications to the substrate sizes that known flipper can handle, in conjunction with the lack of independent control input to change the substrate-handling size of known flippers in-process, limits the applicability of known flippers across different substrates and different processes, and make those known flippers completely un-scalable.

Yet further, known flippers have a substantially open design-that is, the robotics are not encased, at least in part, and so particulate is necessarily generated by known flippers. As such, known flippers are not designed for cleanliness, and are unsuitable for use in clean-room environments.

Further, the typical type of end effector in substantial use in the known art is an edge grip wafer handler. However, these edge grips may exert unwanted friction on the retained wafer, or insufficient friction if a wafer is flipped or rotated sideways, and consequently may provide unpredictable release and/or release positioning of the wafer due to excessive or insufficient wedge-induced friction. Moreover, as edge clamps typically cover a portion of the outer circumference of the wafer, these edge clamps, or the wafer tooling passing proximate to these edge clamps, may cause snags on the wafer and consequently damage the wafer. For example, if a wafer experiences friction and travels with a wedge clamp beyond the release point rather than timely extracting from the clamp, the wafer and/or structures thereon will be damaged.

That is, the simple angle for the edge clamp of the known art limits the ability to invert or rotate a wafer associated with the edge clamp, in part because the angle of the edge clamp is insufficient to retain an inverted or rotated wafer. This problem is exacerbated for thin, flexible, or large wafers, which may require more overlap at the wafer's circumference to retain the wafer, and a steeper edge clamp angle in order to positively capture the wafer, due to the wafer's ability to flex within the clamp, which circumstances may cause self-release of the wafer at an undesired time.

Some semiconductor processing applications may require the use of a rotating wrist end effector. A rotating wrist end effector may require the aforementioned steeper angle and deeper wedge base for the edge clamp, such that the rotation of the end effector will not improperly self-release a wafer from the edge clamp. However, in such an instance, the deeper wedge base and steeper clamp angle are substantially more likely to cause undue friction at the desired timing of release, and thereby negate the self-release of the wafer, causing the lack of the desired release and/or damage to the wafer, by way of non-limiting example.

Accordingly, there is a need for a substrate flipper that is scalable and that provides functionality substantially in accordance with clean room standards.

### SUMMARY

Certain embodiments are and include an apparatus, system and method for a substrate flipper capable of accommodating substrates of varying sizes. The apparatus, system and method may include a base housing providing a rotating feature extending outwardly from the base housing, and including a belt driver; a flipping paddle rotatably associated with the outwardly extending portion of the rotating feature; at least two clamp rails movably resident within slots atop the flipping paddle, each of the at least two clamp rails being associated with a belt driven by the belt driver; and a pair of clamps atop each of the at least two clamp rails, wherein each pair of clamps is opposable to the other pair of clamps, each clamp comprising a lower wedge having therein a spring loaded cam, and an upper wedge against which the spring loaded cam presses an edge of the accommodated substrate upon retention-driving of the belt. After a flipping of the accommodated substrate, an extraction-driving of the belt effects a depression of the spring loaded cam responsive to an increase in distance between the opposing pairs of clamps, thereby ejecting the pressed edge of the accommodated substrate.

The imparted rotation may be up to 180 degrees, back and forth. The flipper may be used in a robot work cell, or in a FOUP (Front Opening Unified Pod) load port accessible to a robot. The flipper paddle may include a motor-driven, such as a servo-driven, self-extracting jaw set that may edge grip the substrate. The self extracting jaws may be used with or without additional Bernoulli vacuum gripping.

Motor-driving the edge clamp gripping may allow for automated adjustment to the proper size “on the fly” for any gripped and flipped substrate. For example, the flipper may handle substrate sizes from 100 mm to 200 mm to 300 mm to 450 mm. Such substrates may include films, semiconductor wafers, glass reticules, solar cells, battery panels, laboratory test samples, or hydrogen fuel cell plates, by way of non-limiting example.

Thus, the disclosure provides at least an apparatus, system and method for providing a substrate flipper that is scalable and that provides functionality substantially in accordance with clean room standards.

### BRIEF DESCRIPTION OF THE DRAWINGS

The exemplary compositions, systems, and methods shall be described hereinafter with reference to the attached drawings, which are given as non-limiting examples only, in which:

FIG. 1 is an illustration of a substrate handling system;

FIG. 2 is an illustration of aspects of a substrate flipper;

FIG. 3 is an illustration of aspects of a substrate flipper;

FIG. 4 is an illustration of aspects of a substrate flipper;

FIG. 5 is an illustration of aspects of a substrate flipper;

FIG. 6 is an illustration of aspects of a substrate flipper;

FIG. 7 is an illustration of aspects of a substrate flipper;

FIG. 8 is an illustration of aspects of a substrate flipper;

FIG. 9 is an illustration of aspects of a substrate flipper; and

FIG. 10 illustrates aspects of a substrate flipper.

### DETAILED DESCRIPTION

The figures and descriptions provided herein may have been simplified to illustrate aspects that are relevant for a clear understanding of the herein described apparatuses, systems, and methods, while eliminating, for the purpose of clarity, other aspects that may be found in typical similar devices, systems, and methods. Those of ordinary skill may thus recognize that other elements and/or operations may be desirable and/or necessary to implement the devices, systems, and methods described herein. But because such elements and operations are known in the art, and because they do not facilitate a better understanding of the present disclosure, for the sake of brevity a discussion of such elements and operations may not be provided herein. However, the present disclosure is deemed to nevertheless include all such elements, variations, and modifications to the described aspects that would be known to those of ordinary skill in the art.

Embodiments are provided throughout so that this disclosure is sufficiently thorough and fully conveys the scope of the disclosed embodiments to those who are skilled in the art. Numerous specific details are set forth, such as examples of specific components, devices, and methods, to provide a thorough understanding of embodiments of the present disclosure. Nevertheless, it will be apparent to those skilled in the art that certain specific disclosed details need not be employed, and that embodiments may be embodied in different forms. As such, the disclosed embodiments should not be construed to limit the scope of the disclosure. As referenced above, in some embodiments, well-known processes, well-known device structures, and well-known technologies may not be described in detail.

The terminology used herein is for the purpose of describing particular embodiments only and is not intended to be limiting. For example, as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The steps, processes, and operations described herein are not to be construed as necessarily requiring their respective performance in the particular order discussed or illustrated, unless specifically identified as a preferred or required order of performance. It is also to be understood that additional or alternative steps may be employed, in place of or in conjunction with the disclosed aspects.

When an element or layer is referred to as being “on”, “upon”, “connected to” or “coupled to” another element or layer, it may be directly on, upon, connected or coupled to the other element or layer, or intervening elements or layers may be present, unless clearly indicated otherwise. In contrast, when an element or layer is referred to as being “directly on,” “directly upon”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). Further, as used herein the term “and/or” includes any and all combinations of one or more of the associated listed items.

Yet further, although the terms first, second, third, etc. may be used herein to describe various elements, components, regions, layers and/or sections, these elements, components, regions, layers and/or sections should not be limited by these terms. These terms may be only used to distinguish one element, component, region, layer or section from another element, component, region, layer or section. Thus, terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the embodiments.

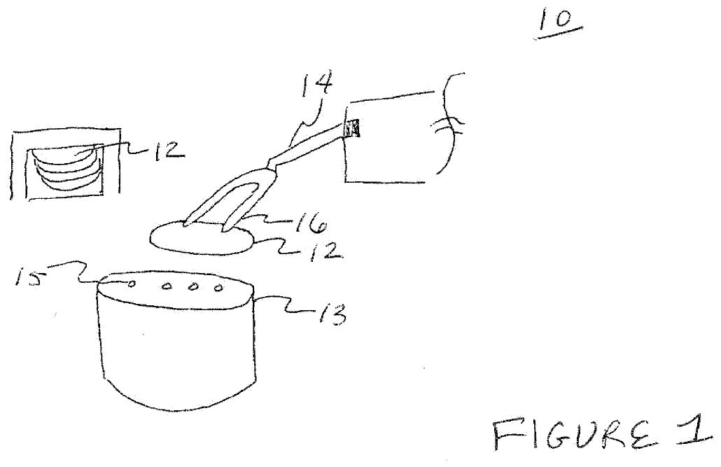

FIG. 1 illustrates an automated substrate handling system 10 suitable to precisely handle substrates, such as semiconductor wafers, films or like-substrates 12, of varying diameters, compositions and physical attributes. The handling system 10 may be capable of handling the substrates 12 in a rapid, ordered succession for processing.

The substrates 12 supplied may be manipulated or transferred among various stationary points 13 for processing, in part, by robotics, such as a robotic armature 14 equipped with an end-effector/gripping system 16 adapted to perform the aforementioned manipulation and transfer. This manipulation and transfer may, for certain stations 13, require that the wafer be flipped or partially rotated for processing at the station 13. The stationary points 13 may then suitably grip 15 the substrates 12 upon placement, such as for the aforementioned processing of the substrate.

Not only may substrates 12 vary in shape or diameter, they are also typically manufactured according to standardized specifications which, among other dimensional tolerances including the diameter, may require the surface of the substrates 12 to be, and to be maintained during processing as, substantially planar. As such, flipping/rotating of an in-process substrate must not adversely affect the planarity of the substrate, and must not adversely affect the structures processed on the substrate.

Substrates 12 for processing may be silicon wafers, by way of example, such as 200 mm silicon wafers, for example, which may have one standard diameter of 200+/−0.2 mm and one standard thickness such as 675+/−25 microns. A typical wafer thickness after processing may range from about 500 microns to about 700 microns.

The illustrated substrate 12 may be maintained upon the end effector 16 by, for example, clamps. Likewise, the substrate may be retained upon the disclosed flipping paddle for flipping by clamps in the instant embodiments. Such clamps may be “edge” clamps that contact only the very fine edge of the substrate, so as to avoid the clamp adversely affecting the in-process surfaces of the wafer. For example, two pairs of opposing edge clamps may provide edge clamping at four “corners” across the arc of the gripped substrate. That is, opposing edge clamp pairs may be used in a “corners” configuration for the disclosed flipper. Additionally in the disclosed flipper, the edge clamps may include retaining and extracting features to allow for flipping of the substrate without displacement of the substrate during flipping.

More specifically, once gripped, such as by edge clamps, the gripped substrate 12 may be rotated by the disclosed substrate flipper. The rotation may be imparted by a rotating feature that rotates a flipping paddle, as discussed throughout. The rotating feature may provide for rotation from 0° (i.e., the horizontal aspect of the flipping paddle resident on the horizontal axis) to 180°, +/−0.05°, by way of nonlimiting example. The rotating feature, the module/base housing, and/or the rotating feature may include, by way of nonlimiting example, travel stops, such as to maintain positional repeatability. By way of example, the rotation axes may have a highly refined repeatability, such as in the range of 1 to 5 μm, or more particularly 2 μm.

The rotating feature may be set within any rigid base housing, such as a billet aluminum or stainless steel base. The base may fully or partially enclose the electronics and mechanicals for the rotation feature, as well as the clamping pair actuator, thereby enhancing workstation cleanliness. In some embodiments, the module/base housing may provide a clean room level enclosure that maintains particulate therein, without risk of polluting the workspace. As such, the base enclosure may comprise a vacuum and/or be vacuum scavenged, and may be formed of a suitable material to maintain cleanliness, such as the aforementioned stainless steel.

The rotating feature within the base housing may comprise a gear head having a bearing or bearings in rotating communication with the rotating feature, and a motor to provide the rotation disclosed throughout. Although the rotator motor may comprise a servo motor, which may rotate on a high load capacity cross roller bearing, other motor types, such as a stepper motor, may be used. The disclosed gear head may also include backlash compensation.

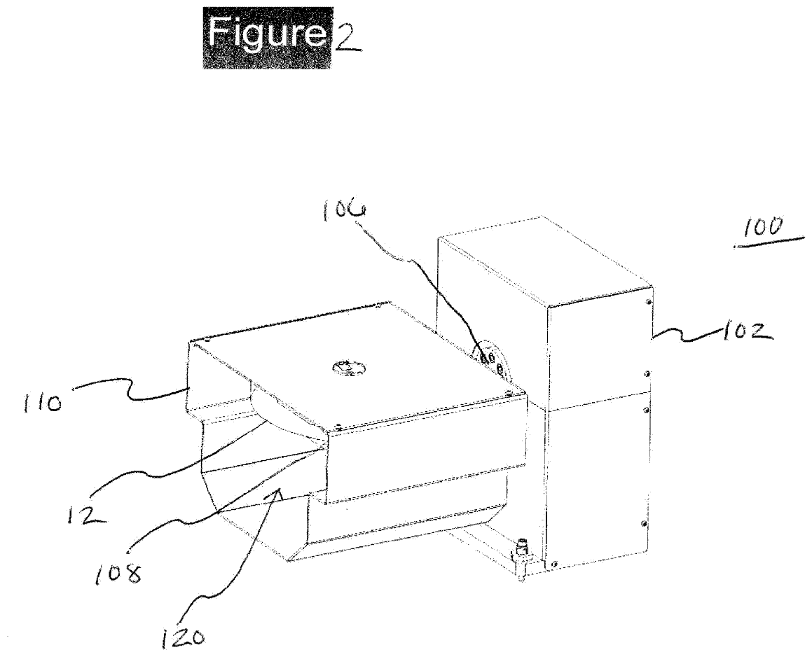

With reference now also to FIG. 2 (A), illustrated is an exemplary modular edge gripping substrate flipper 100. Of note, although aspects are discussed herein particularly with respect to edge gripping, vacuum gripping may also be employed throughout and as noted. Moreover, although the illustrated module comprises a table top base housing 102, i.e., a table top flipping module, the skilled artisan will appreciate that the module may be other than a table top flipper yet still constitute a modular substrate flipper 100 in accordance with the disclosure.

The figure illustrates a table top base/column-style housing 102 at least mechanically associated 106 with a flipping paddle 108 that is within a paddle enclosure 110. The column housing 102 may provide the mechanical, electrical, and communication aspects discussed throughout and which enable the flipping of flipping paddle 108 (and consequently the paddle enclosure 110) by, for example, up to 180 degrees. The paddle enclosure 110 may provide accessibility 120 at the front side thereof, i.e., opposite the column housing 102, to enable access to the substrate 12 by, for example, an end effector 16 used in semiconductor processing as referenced above in FIG. 1.

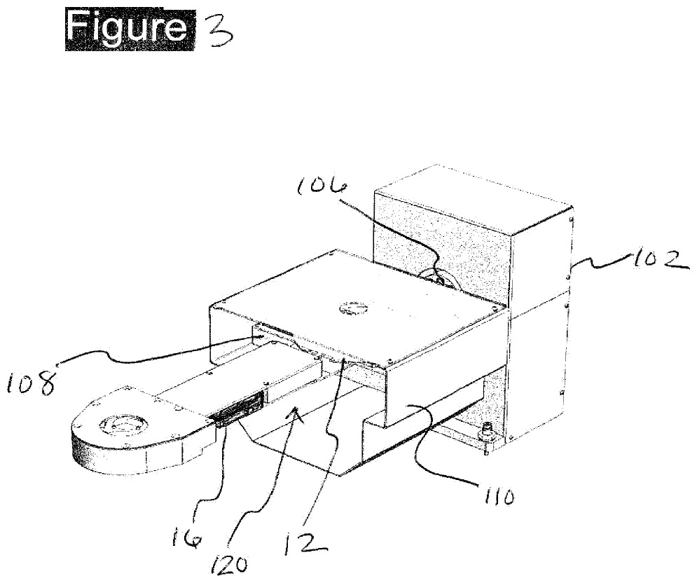

By way of example, FIG. 3 (B) illustrates an end effector 16 reaching into the flipper enclosure 110 to grip, for example, a semiconductor wafer 12 in a size range of 100 mm-300 mm through the access 120 of the paddle enclosure 110. Needless to say, the purpose of the reach-through is to ultimately associate the substrate 12 with the flipping paddle 108 within the paddle enclosure 110. Although typical, but not required, of use circumstances of the disclosed embodiments, the end effector 16 of FIG. 3 does not have a wristing capability, i.e., the end effector 16 will be unable to flip the wafer 12, and thus the need for the disclosed flipping paddle 108 arises.

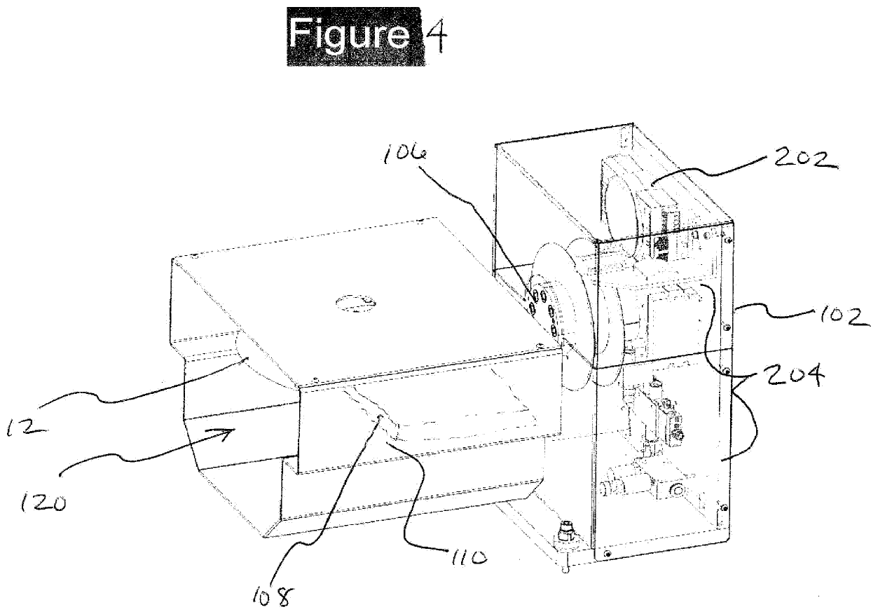

FIG. 4 (C) illustrates with greater particularity certain aspects of the module/column-style housing 102. As illustrated, the module housing 102 may include network and/or user interface connectivity 202 for controlling the gripping and flipping of a substrate 12 associated with the flipping paddle 108. The module housing 108 may additionally include electro-mechanical aspects 204 to allow for actuation of the disclosed grippers, vacuum, and/or paddle rotating feature, as discussed above. Needless to say, the base housing 102 may or may not include a wrapped electronic wiring harness with one or more motion connectors/knuckles that allow for movement of the wiring with rotation of the flipper and/or movement of the clamp rails as discussed throughout.

By way of example, a servo or a stepper motor, such as with precision motor encoding, as well as theta axis pneumatics, may also be present within the modular housing 102. Of course, numerous other electrical, mechanical and/or safety features 204 may also be associated with the module housing. By way of example, shock stops may provide braking for paddle rotation, such as to prevent substrate damage or loss during paddle rotation. By way of further example, the housing 102 may include sensors, such as a substrate presence sensor, which, in part, may control operation of the flipping paddle 108.

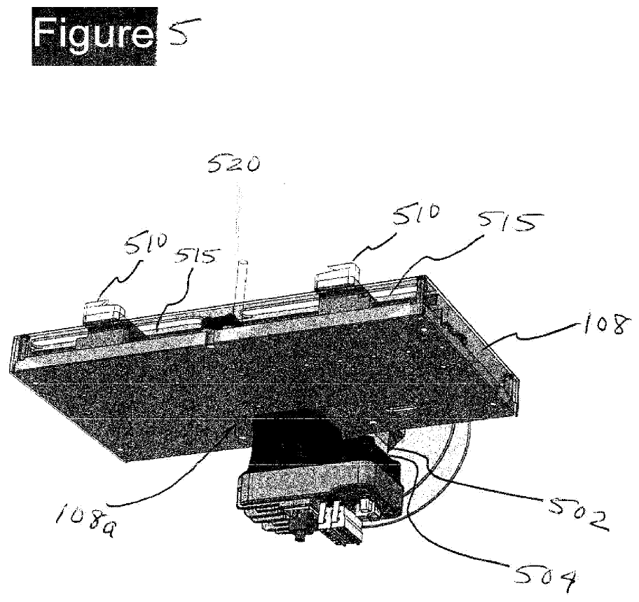

FIG. 5 (D) is an illustration of a bottom-front view of the flipping paddle 108. As illustrated, the rotator 502, such as a programmable stepper or servo motor, may engage the flipping paddle 108 on the substrate non-contact side 108a thereof, such as at the bottom-rear portion of the paddle 108. Accordingly, this interface between the rotator 502 and the paddle 108 may further include, for example, electronics interface(s), encoders 504, sensors, and so on.

The substrate-side of the paddle may include clamps 510, such as edge gripper components, and these edge gripping components may include adjustable aspects, such as those discussed herein, capable of adjustments to accommodate differently-sized substrates. That is, these clamps may be slot-driven 515. Moreover, these edge clamps 510 may include self-retaining and/or self-extracting aspects, such as may be actuated in the course of size adjustment as detailed more fully below.

In the illustration, the adjustment aspects are slot-driven 515 within the paddle 108 for adjusting the edge clamps 510, although other manner of associating the adjustments with the edge clamps 510 may be employed. Further, although two edge clamps 510 are shown at the upper-front of the paddle 108 for retaining the arc of a substrate associated with the flipping paddle (the two upper-rear clamps are not shown in FIG. 5), it will be appreciated that other numbers of clamps, such as one, may be present at the upper-front portion of the flipping paddle, such as in embodiments where odd-numbers of clamps are used.

Also illustrated is an ultrasonic sensor 520 associated with the upper-portion of the paddle. Of course, other types of sensors, such as to sense presence or other substrate features, may be used with or instead of the illustrated ultrasonic sensor, although an ultrasonic sensor, such as the one illustrated, offers the additional benefit of being able to sense both opaque and transparent substrates.

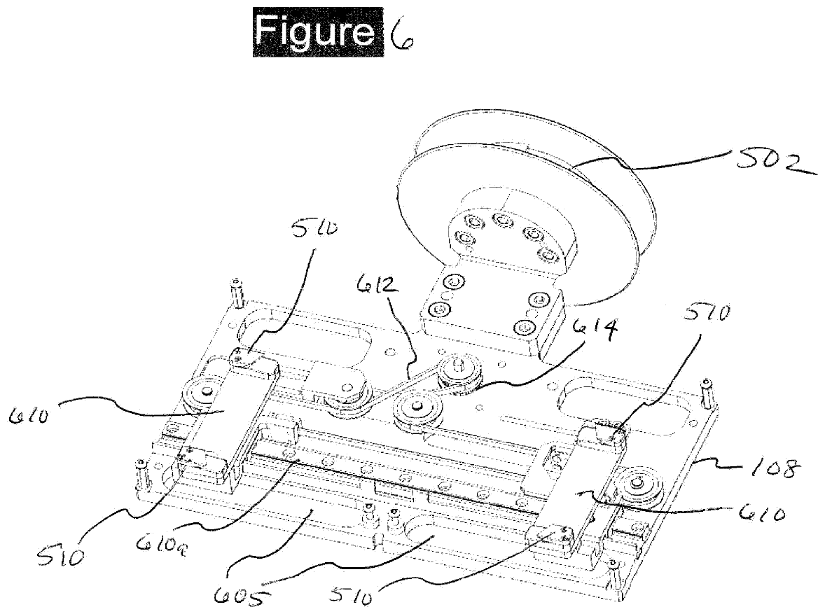

FIG. 6 (E) illustrates a top view of the flipping paddle 108. In the illustration, four self extracting clamps 510 are shown, although other numbers of clamps may be used. Each of the “right” and “left” pairs of the clamps 510 are associated with slot-driven 605 clamp rails 610 which, upon actuation, move towards and away from each other to provide both the substrate size adjustment and the retention/extraction of the substrate to/from the clamps 510 (if self-extracting clamps are used). In the embodiment shown, these clamp rails 610 are belt-driven 612 from a single motor drive 614, and thereby the slot-driven clamp expansion or contraction may be synchronous as shown. The belt 612 may be composed of, for example, rubber or polyurethane. The belt 612 may be horizontally or vertically disposed in relation to the horizontal plane of the flipping paddle 108. Of course, it will be appreciated that other methodologies of driving the rails 610, either synchronously or asynchronously, may be employed.

Simply put, as illustrated the right pair of edge clamps 510 may be slot-driven 605 by the drive belt 612 toward and away from the left pair. A decrease in the distance between each respective pair of edge clamps exerts greater friction on the edge of the retained substrate gripped therebetween, and, particularly for a self-extracting edge clamp, thus causes the circumferential edges of the substrate between each respective pair of edge clamps to exert loading pressure on, for example, springs associated with each respective edge clamp pair.

The use of self-extracting edge clamps helps ensure that released components are released when desired, and stay substantially or completely in the desired position, such as staying centered on the edge clamp during flipping. These clamps, as well as the vacuum pads discussed below, may provide both improved grip of the gripped item, as well as static electricity dissipation during handling and processing.

Yet more particularly, the edge clamps disclosed may include a spring-loaded sliding cam, or “puck”, that positively extracts a wafer from the edge clamp's grip, such as when the pressure exerted by an opposing “corner” edge clamp is released, i.e., when the opposing rail pair is moved closer to the other rails pair. That is, the disclosed extraction may be passive. Of course, the skilled artisan will appreciate, in light of the discussion herein, that the extraction cam may not only be passive as disclosed, but may also be active, such as being pneumatically or electrically driven.

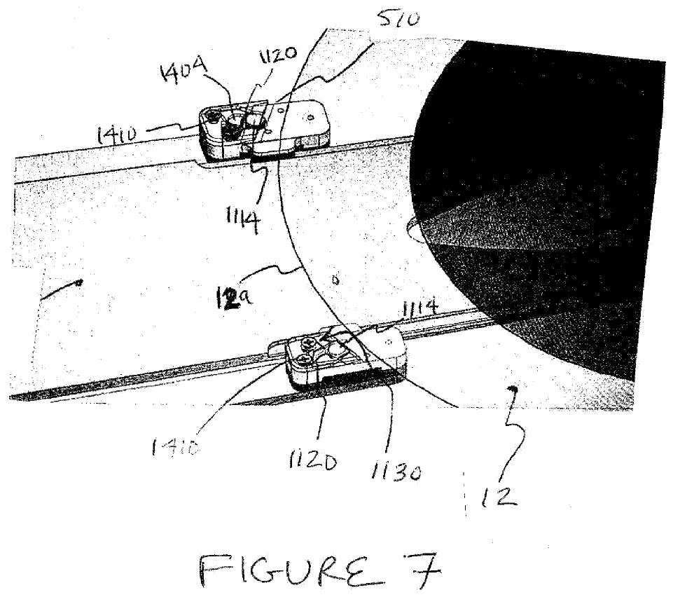

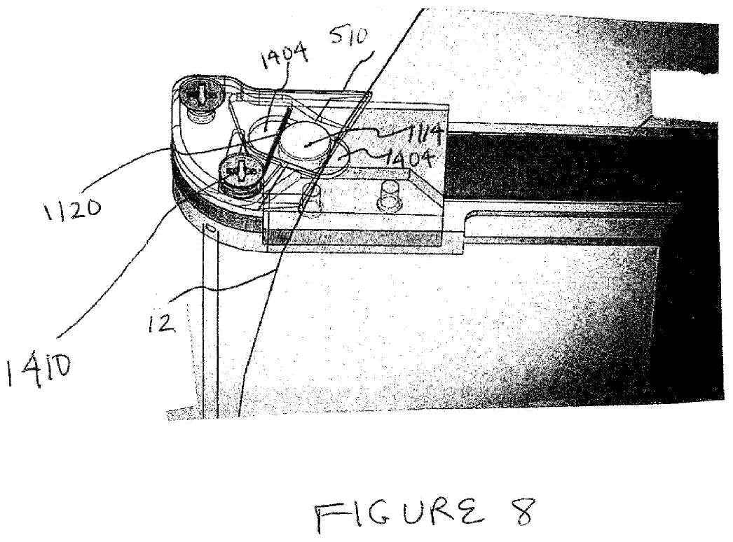

More particularly, and with reference now additionally to FIGS. 7 and 8 (5, 7 . . . B), the application of loading pressure on each self-extracting clamp 510 caused by the decrease in distance between each pair of edge clamps may spring load an extraction cam 1114 into the respective wedge-shaped housing 1130, thereby gripping the substrate's circumferential edge within each respective edge clamp 510. This enhanced frictional gripping of the circumferential edge of the substrate thus allows for an increase in available angling of a retained substrate 12, and thereby results in an improved substrate grip during flipping.

With particular reference now to FIG. 7 (5 . . . B), the gripping of the substrate 12 upon contraction of the edge clamp pairs together causes a compression of the springs 1120 associated with each extraction cam 1114, and consequently allows for application of each wedge over the circumferential edge of the retained substrate 12, thus firmly gripping the substrate even when flipped. On the contrary, an increase in the distance between each pair of edge clamps causes a decompression of the spring 1120 on each extraction cam 1114, thereby causing the extraction cam 1114 to spring outwardly from the body of each wedge clamp, thus ejecting the edge of the substrate previously gripped.

More particularly, each of the edge clamps may include a sunk extraction cam 1114 within a sunk extraction cam guide 1404 that allows the extraction cam 1114 to be placed in compressed and decompressed positions. Furthermore, although the spring 1120 of each respective extraction cam 1114 may be physically associated with any aspect of the edge clamp housing to provide a base for application of the spring force, the springs 1120 may specifically be associated with one or more screws 1410 used to screw each wedge clamp onto its respective portion of the edge rail.

FIG. 8 (7 . . . B) illustrates a top cut away view of an exemplary self-extracting edge clamp that may provide springs that enable self-extraction, such as may be used in ones of the embodiments. As shown, an extraction cam spring 1120 may be loaded about a mounting screw 1410 for the edge clamp.

The extraction cam 1114 is then pushed inwardly from the flush position of the edge clamp's angled portion edge by exertion of pressure from the circumferential portion of the retained substrate. The extraction cam 1114 resides within a sunk guide 1404, wherein the sunk guide 1404 is sufficient in length so as to allow the extraction cam 1114 to be in the fully compressed and fully decompressed position, based on the spring loading compression pressure applied by the substrate's edge to the extraction cam 1114.

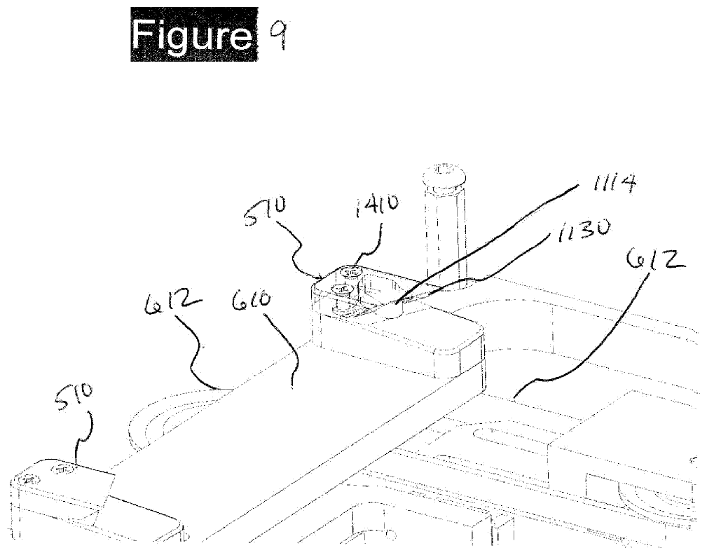

FIG. 9 (G) illustrates a belt-driven, single motor clamp rail drive system for a self-extracting edge clamp system. As shown, the single belt 612 driven by the slot-drive motor 614 (not shown in FIG. 9) may modify the distance between the edge clamp pairs 510 discussed above. The modification in this distance may also actuate the self extracting edge clamps discussed above. Thereafter, an increase in the slot-distance between the edge clamp pairs 510 may cause the referenced self-extraction of the edge-gripped wafer after flipping, by way of example.

A plurality of Bernoulli pads may be added in some embodiments, such as along the drive rails, to the upper paddle. These Bernoulli pads may allow for modification or elimination of the disclosed self-extracting edge clamps. For example, the use of vacuum may allow for the clamps to not have a top portion to retain a substrate during flipping; the vacuum may allow for elimination of the need for self-extraction of the wafer edge, and for the use of a vacuum turn-off instead for extraction purposes; or the vacuum may allow for the use of fewer than four edge clamps, such as the use of zero, two or three edge clamps.

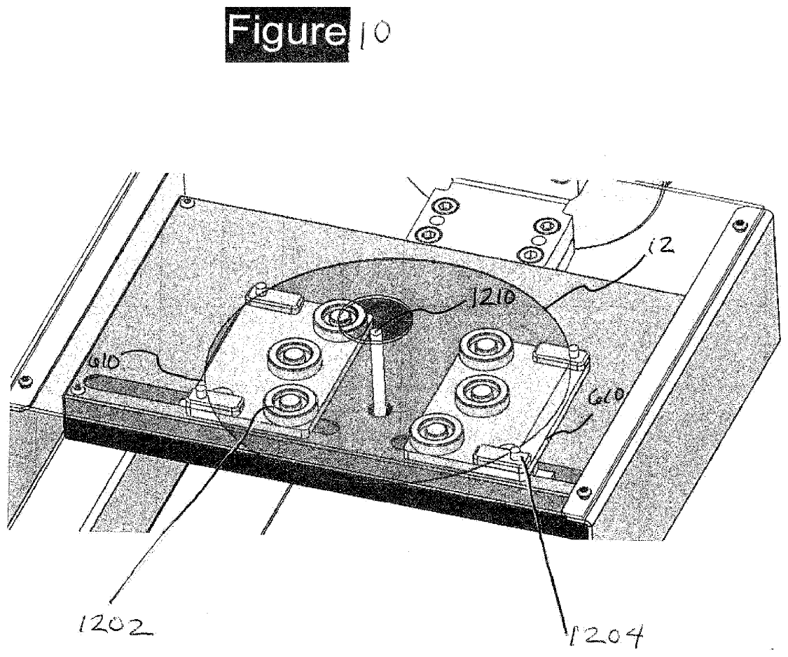

The foregoing embodiment is shown in FIG. 10 (F). More particularly, in the illustration, a plurality of Bernoulli pads 1202 are provided on each slot-rail 610, and in addition a pair of simple edge-containment clamps 1204 (rather than the self-extracting edge clamps also referenced herein, which may likewise be used in the embodiment of FIG. 10) are provided at the distal portions of each of the “right” and “left” slot rails 610. Also included in the embodiment of FIG. 10 is the ultrasonic sensing 1210 referenced throughout.

The foregoing apparatuses, systems and methods may also include the control of the various robotic and vacuum functionality referenced throughout. Such control may include, by way of non-limiting example, manual control using one or more user interfaces, such as a controller, a keyboard, a mouse, a touch screen, or the like, to allow a user to input instructions for execution by software code associated with the robotics and with the systems discussed herein. Additionally, and as is well known to those skilled in the art, system control may also be fully automated, such as wherein manual user interaction only occurs to “set up” and program the referenced functionality, i.e., a user may only initially program or upload computing code to carry out the predetermined movements and operational sequences discussed throughout. In either a manual or automated embodiment, or in any combination thereof, the control may be programmed, for example, to relate the known positions of substrates, the robotics, the stationary point, and the relative positions there between, for example.

It will be appreciated that the herein described systems and methods may operate pursuant to and/or be controlled by any computing environment, and thus the computing environment employed not limit the implementation of the herein described systems and methods to computing environments having differing components and configurations. That is, the concepts described herein may be implemented in any of various computing environments using any of various components and configurations.

Further, the descriptions of the disclosure are provided to enable any person skilled in the art to make or use the disclosed embodiments. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but rather is to be accorded the widest scope consistent with the principles and novel features disclosed herein.

What is claimed is:

1. A substrate flipper capable of accommodating substrates of varying sizes, comprising:
a base housing providing a rotating feature extending outwardly from the base housing, and including a belt driver;
a flipping paddle rotatably associated with the outwardly extending portion of the rotating feature;
at least two clamp rails movably resident within slots atop the flipping paddle, each of the at least two clamp rails being associated with a belt driven by the belt driver; and
a pair of clamps atop each of the at least two clamp rails, wherein each pair of clamps is opposable to the other pair of clamps, each clamp comprising a lower wedge having therein a spring loaded cam, and an upper wedge against which the spring loaded cam presses an edge of the accommodated substrate upon retention-driving of the belt;
wherein, after a flipping of the accommodated substrate, an extraction-driving of the belt effects a depression of the spring loaded cam responsive to an increase in distance between the opposing pairs of clamps, thereby ejecting the pressed edge of the accommodated substrate.

2. The substrate flipper of claim 1, wherein the base housing includes a power and electronic data interface.

3. The substrate flipper of claim 1, wherein the rotation comprises 180 degrees from a horizontal axis.

4. The substrate flipper of claim 1, wherein the substrate comprises one selected from the group consisting of a film frame, a semiconductor wafer, a processed wafer, and a glass reticle.

5. The substrate flipper of claim 4, wherein the substrate has a diameter in a range of 100 mm to 300 mm.

6. The substrate flipper of claim 1, further comprising an enclosure capable of substantially enclosing the flipping paddle and rotating with the flipping paddle.

7. The substrate flipper of claim 1, wherein the actuation of the belt driver is automatic.

8. The substrate flipper of claim 1, further comprising at least one sensor of the substrate.

9. The substrate flipper of claim 8, wherein the sensor is ultrasonic.

10. The substrate flipper of claim 1, wherein each of the clamp rails further comprises a plurality of Bernoulli vacuum pads.

11. The substrate flipper of claim 10, wherein a vacuum to the Bernoulli vacuum pads is provided from the base housing.

12. The substrate flipper of claim 1, wherein a plane of the driven belt is vertical in relation to a horizontal plane provided by the flipping paddle.

13. The substrate flipper of claim 1, wherein the base housing is vacuum-scavenged.

14. The substrate flipper of claim 1, wherein the base housing comprises stainless steel.

15. The substrate flipper of claim 1, wherein the base housing comprises a wrapped electronic wiring harness that moves with rotation of the two arms.

16. The substrate flipper of claim 1, wherein the increase in distance is synchronized between the rails.

17. The substrate flipper of claim 16, wherein the synchronization is provided by the driven belt.

18. The substrate flipper of claim 17, wherein the driven belt is composed of polyurethane.

19. The substrate flipper of claim 1, wherein the rotating feature comprises a motor.

20. The substrate flipper of claim 19, wherein the motor is encoded.
